(19) United States
(12) Patent Application Publication
(10) Pub. No.: US 2026/0133613 A1
(43) Pub. Date: May 14, 2026

(54) THERMAL MANAGEMENT FOR AN ELECTRICAL COMPONENT

(71) Applicant: TE Connectivity Solutions GmbH, Schaffhausen (CH)

(72) Inventor: Alan Weir Bucher, Middletown, PA (US)

(21) Appl. No.: 18/947,175

(22) Filed: Nov. 14, 2024

(51) Int. Cl. G06F 1/20; H05K 7/20

(52) U.S. Cl. CPC G06F 1/206; H05K 7/20445

(57) ABSTRACT

A communication system includes a first electrical component having a board connector mounted to a host circuit board and a heat transfer assembly with a thermal bridge mounted to a heat transfer element. The communication system includes a second electrical component received in a component space between the host circuit board and the heat transfer assembly being thermally and electrically coupled to the first electrical component. The second electrical component includes a receptacle connector mounted to a circuit card configured to be electrically connected to a pluggable module. The circuit card is electrically connected to the board connector. A receptacle cage of the second electrical component includes a module channel receiving the receptacle connector and the pluggable module. The receptacle cage includes a thermal opening open at the upper wall and the rear wall that receives the thermal bridge to allow the thermal bridge to interface with the pluggable module in the module channel.

### BACKGROUND OF THE INVENTION

The subject matter herein relates generally to thermal management for electrical components.

It may be desirable to transfer thermal energy (or heat) away from designated components of a system or device. Some systems use electrical components, such as electrical connectors, to transmit data and/or electrical power to and from different systems or devices. Some systems use electrical components, such as pluggable modules for transmitting data signals through communication cable(s) in the form of optical signals and/or electrical signals. Some systems use electrical components, such as integrated circuits, for controlling the system. The electrical components define heat generating sources within the system.

A common challenge that confronts developers of electrical systems is heat management. Thermal energy generated by electrical components within a system can degrade performance or even damage components of the system. To dissipate the thermal energy, systems include a thermal component, such as a heat sink, which engages the heat source, absorbs the thermal energy from the heat source, and transfers the thermal energy away. For example, the thermal component is typically mounted to the EMI cage and extends into the interior chamber of the EMI cage to interface with the pluggable I/O module when the pluggable I/O module is plugged into the EMI cage. The amount of heat dissipation from such systems may be limited and some known electrical systems include a cold plate to dissipate heat from the heat generating components. Interfacing the cold plate with the heat generating component (for example, the pluggable I/O module) can be challenging.

There is a need for a thermal management system that efficiently transfers thermal energy away from an electrical component.

### BRIEF DESCRIPTION OF THE INVENTION

In one embodiment, a communication system is provided and includes a first electrical component that includes a host circuit board having a first surface and a board connector mounted to the first surface. The first electrical component includes a heat transfer assembly that includes a heat transfer element. The heat transfer element includes a thermal surface spaced apart from the first surface forming a component space between the first surface and the thermal surface. The heat transfer assembly includes a thermal bridge in the component space that includes a first thermal interface thermally coupled to the thermal surface and a second thermal interface opposite the first thermal surface. The communication system includes a second electrical component received in the component space and is thermally and electrically coupled to the first electrical component. The second electrical component includes a circuit card having a first surface and a receptacle connector mounted to the first surface. The receptacle connector is configured to be electrically connected to a pluggable module. The circuit card is electrically connected to the board connector. The second electrical component includes a receptacle cage coupled to the circuit card. The receptacle cage includes cage walls includes an upper wall, a lower wall, a first side wall, a second side wall, and a rear wall. The receptacle cage includes a module channel between the upper and lower walls and between the first and second sides walls and between the front and rear walls. The module channel receives the receptacle connector therein at a rear of the receptacle cage. The module channel configured to receive the pluggable module through a port at a front of the receptacle cage. The receptacle cage includes a thermal opening open at the upper wall and the rear wall. The thermal opening receives the thermal bridge of the heat transfer assembly to allow the thermal bridge to interface with the pluggable module in the module channel.

In another embodiment, an electrical component is provided and includes a host circuit board that includes a first surface. The electrical component includes a board connector mounted to the first surface of the host circuit board. The board connector is configured to be electrically connected to a mating electrical component. The electrical component includes a heat transfer assembly that includes a heat transfer element. The heat transfer element includes a thermal surface spaced apart from the first surface forming a component space between the first surface and the thermal surface configured to receive the mating electrical component. The heat transfer assembly includes a thermal bridge in the component space. The thermal bridge includes a first thermal interface thermally coupled to the thermal surface and a second thermal interface configured to be thermally coupled to the mating electrical component in the component space.

In a further embodiment, an electrical component is provided and includes a circuit card that includes a first surface. The electrical component includes a receptacle connector mounted to the first surface of the circuit card. The receptacle connector is configured to be electrically connected to a pluggable module. The electrical component includes a receptacle cage coupled to the circuit card. The receptacle cage includes an upper wall, a lower wall, a first side wall, a second side wall, and a rear wall. The receptacle cage includes a module channel between the upper and lower walls and between the first and second sides walls and between the front and rear walls. The module channel receives the receptacle connector therein at a rear of the receptacle cage. The module channel configured to receive the pluggable module through a port at a front of the receptacle cage. The receptacle cage includes a thermal opening open at the upper wall and the rear wall configured to receive a thermal bridge of a heat transfer assembly to allow the thermal bridge to interface with the pluggable module in the module channel.

### BRIEF DESCRIPTION OF THE DRAWINGS

FIG. 1 is a front perspective view of a communication system formed in accordance with an exemplary embodiment.

FIG. 2 is a perspective view of the first electrical component in accordance with an exemplary embodiment.

FIG. 3 is a perspective view of the thermal bridge in accordance with an exemplary embodiment.

FIG. 4 is a sectional view of the thermal bridge in accordance with an exemplary embodiment.

FIG. 5 is a cross-sectional view of the thermal bridge in accordance with an exemplary embodiment.

FIG. 6 is a perspective view of the second electrical component in accordance with an exemplary embodiment.

FIG. 7 is a perspective view of a portion of the second electrical component in accordance with an exemplary embodiment.

FIG. 8 is a perspective view of the communication system showing the second electrical component partially mated with the first electrical component in accordance with an exemplary embodiment.

### DETAILED DESCRIPTION OF THE INVENTION

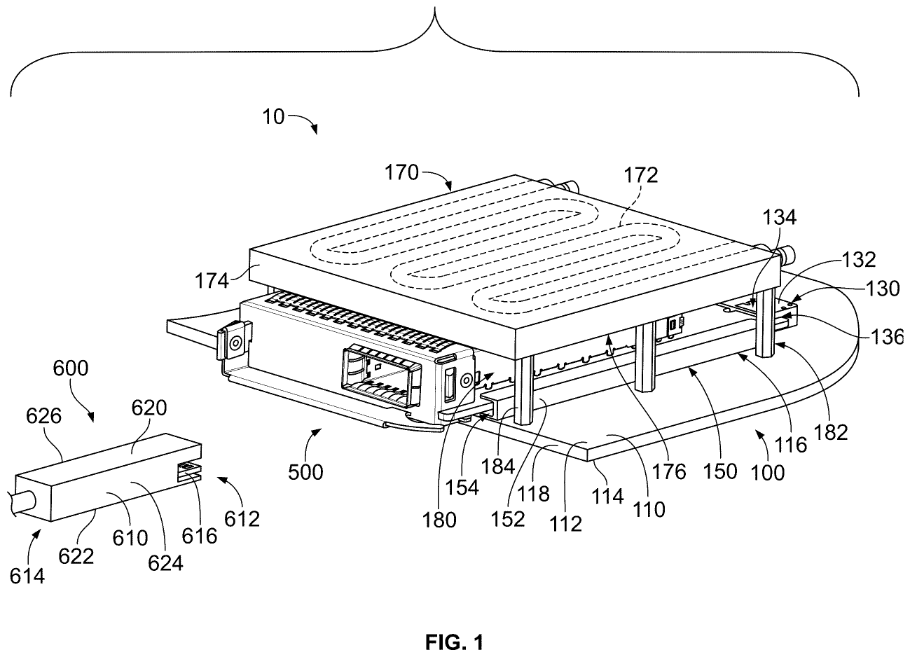

FIG. 1 is a front perspective view of a communication system 10 formed in accordance with an exemplary embodiment. The communication system 10 includes a heat dissipating components for thermal management of components of the communication system 10. The communication system includes a first electrical component 100 and a second electrical component 500 coupled to the first electrical component 100. In an exemplary embodiment, the thermal management system is incorporated into the first electrical component 100 and is configured to dissipate heat from the second electrical component 500 when mated therewith.

In an exemplary embodiment, the second electrical component 500 includes a pluggable module 600 pluggable into the second electrical component 500 (and removable from the second electrical component 500). The pluggable module 600 may be an I/O module, such as a transceiver module. Other types of electrical components may be provided in alternative embodiments. In an exemplary embodiment, the thermal management system is used to dissipate heat from the pluggable module 600 when the pluggable module 600 is plugged into the second electrical component 500.

In an exemplary embodiment, the second electrical component 500 is a pluggable component configured to be plugged into the first electrical component 100. The second electrical component 500 is configured to be electrically coupled to the first electrical component 100. The second electrical component 500 is configured to be thermally coupled to the first electrical component 100. In an exemplary embodiment, the second electrical component 500 is a network interface card.

In an exemplary embodiment, the pluggable module 600 has a pluggable body 610, which may be defined by one or more shells. The pluggable body 610 may be thermally conductive and/or may be electrically conductive, such as to provide EMI shielding for the pluggable module 600. The pluggable body 610 includes a mating end 612 and a cable end 614 opposite the mating end 612. The mating end 612 is configured to be inserted into the second electrical component 500, such as into a socket or port of the second electrical component 500. A cable extends from the cable end 614, such as to another component within the system.

The pluggable module 600 includes a connector interface configured to be electrically connected to the second electrical component 500 (such as to a receptacle connector thereof). In an exemplary embodiment, the connector interface includes a module circuit card 616 having a card edge configured to be plugged into a card slot of the receptacle connector of the second electrical component 500. The module circuit card 616 is accessible at the mating end 612. The module circuit card 616 has a mating edge and mating contacts (for example, circuits, pads, traces, etc.) at the mating edge configured to be mated with the receptacle connector. The module circuit card 616 may include components, circuits and the like used for operating and/or using the pluggable module 600. For example, the module circuit card 616 may have conductors, traces, pads, electronics, drivers, sensors, controllers, switches, inputs, outputs, and the like associated with the pluggable module 600, which may be mounted to the module circuit card 616, to form various circuits. Heat generated by the components of the pluggable module 600 may be dissipated by the thermal management system. In various embodiments, the pluggable module 600 may be a fiber optic module. The pluggable module 600 may include fiber optic cables and/or optical generators to transmit optical signals.

The pluggable module 600 includes an outer perimeter defining an exterior of the pluggable body 610. For example, the outer perimeter may be defined by a top 620, a bottom 622, a first side 624 and a second side 626. The pluggable body 610 may have other shapes in alternative embodiments. The top 620 may be planar and define a thermal interface for the pluggable module 600, such as to interface with the heat dissipating elements of the first electrical component 100.

In an exemplary embodiment, the pluggable body 610 provides heat transfer for the module circuit card 616, such as for the electronic components on the module circuit card 616. For example, the module circuit card 616 is in thermal communication with the pluggable body 610 and the pluggable body 610 transfers heat from the heat generating components.

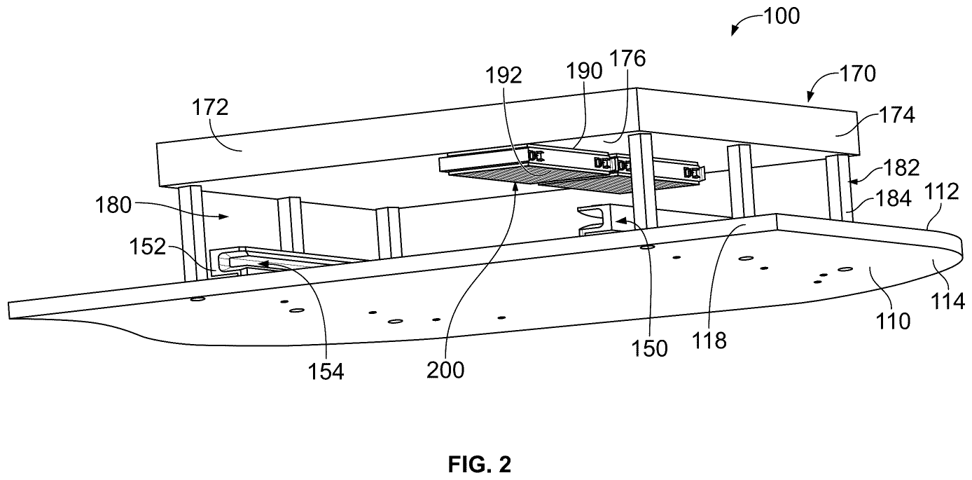

With additional reference to FIG. 2, which is a perspective view of the first electrical component 100 in accordance with an exemplary embodiment, the first electrical component 100 includes a host circuit board 110 and a board connector 130 (FIG. 1) mounted to the host circuit board 110. The first electrical component 100 includes a guide assembly 150 positioned relative to the board connector 130 to guide mating with the second electrical component 500. The first electrical component 100 includes a heat transfer assembly 170 to dissipate heat from the second electrical component 500 (for example, from the pluggable module 600) when the second electrical component 500 is mated with the first electrical component 100.

The host circuit board 110 includes an upper surface 112 and a lower surface 114. The host circuit board 110 includes one or more circuits (for example, traces, pads, vias, and the like) on one or more layers of the host circuit board 110. The host circuit board 110 includes an interface area 116 configured to interface with the second electrical component 500. For example, the interface area 116 may be located at the upper surface 112, such as proximate to an edge 118 of the host circuit board 110. The interface area 116 may be defined by the footprint of the board connector 130 and/or the guide assembly 150 and/or the heat transfer assembly 170. The host circuit board 110 may host other electrical components, such as a processor, IC component, memory component, or other types of electrical components.

The board connector 130 is electrically connected to the host circuit board 110. For example, the board connector 130 may be mounted to the upper surface 112 of the host circuit board 110. The board connector 130 may be soldered to circuits of the host circuit board 110. In an exemplary embodiment, the board connector 130 includes a board connector housing 132 holding board connector contacts 134. The board connector contacts 134 are configured to be electrically connected to the corresponding circuits (for example, pads, of the host circuit board 110. In an exemplary embodiment, the board connector housing 132 is a card edge connector having a card slot 136 at a front of the board connector housing 132. The card slot 136 is configured to receive a card edge of a circuit card of the second electrical component 500 in a loading direction, which may be parallel to the upper surface 112 of the host circuit board 110. Other types of electrical connectors may be used in alternative embodiments.

The guide assembly 150 is used to guide mating of the second electrical component 500 with the first electrical component 100. In an exemplary embodiment, the guide assembly 150 includes one or more guide rails 152 mounted to the host circuit board 110. Each guide rail 152 includes a guide track 154. The guide track 154 is configured to receive a portion of the second electrical component 500. For example, the guide track 154 may receive the circuit card of the second electrical component 500 to guide the circuit card for mating with the board connector 130. In the illustrated embodiment, the guide track 154 extends parallel to the upper surface 112 of the host circuit board 110. In an exemplary embodiment, the guide rail 152 is configured to horizontally position the second electrical component 500 and/or vertically position the second electrical component 500, such as for mating with the board connector 130. The guide rail 152 may align the circuit card of the second electrical component 500 with the card slot 136. The guide rail 152 may orient the circuit card parallel to the host circuit board 110. Other types of guide features may be used in alternative embodiments to guide mating of the second electrical component 500 with the first electrical component 100.

The heat transfer assembly 170 is used to dissipate heat from the second electrical component 500. In an exemplary embodiment, the heat transfer assembly 170 includes a heat transfer element 172. The heat transfer element 172 may be a conductive cooling device. In the illustrated embodiment, the heat transfer element 172 is a cold plate. For example, the heat transfer element 172 includes a metal block 174 used as a heat exchanger. In an exemplary embodiment, the metal block 174 may include a series of loops, channels or tubes running through the metal block 174 to allow cooling liquid to circulate through the metal block 174. The metal block 174 may be an aluminum block, a copper block, or another metal material. Other types of heat transfer elements may be used in alternative embodiments, such as a heatsink having cooling fins for convective airflow cooling over the surface of the heat sink. The heat transfer element 172 includes a thermal surface 176 configured to interface with the second electrical component 500 or an intermediary heat transfer element.

In an exemplary embodiment, a thermal bridge 200 (FIG. 2) is configured to be positioned between the thermal surface 176 and the second electrical component 500 to form a thermal interface between the heat transfer element 172 and the second electrical component 500. The thermal bridge 200 includes a first (or upper) thermal interface thermally coupled to the thermal surface 176 and a second (or lower) thermal interface opposite the first thermal surface configured to interface with the second electrical component 500. In an exemplary embodiment, the thermal bridge 200 may be mounted to the heat transfer element 172, such as being fastened, clipped, latched, welded, or otherwise fixed to the heat transfer element 172. The heat transfer element 172 positions the thermal bridge 200, such as relative to the host circuit board 110 and/or the board connector 130 for mating with the second electrical component 500. For example, the thermal bridge 200 may be suspended from the bottom surface of the heat transfer element 172 to interface with the top surface of the second electrical component 500 when the second electrical component 500 is plugged into the space between the heat transfer element 172 and the host circuit board 110.

The heat transfer element 172 is spaced apart from the upper surface 112 of the host circuit board 110. For example, a component space 180 is defined between the upper surface 112 and the thermal surface 176. The component space 180 is configured to receive the second electrical component 500. The thermal bridge 200 is located in the component space 180 to interface with the second electrical component 500. In an exemplary embodiment, one or more support elements 182 are used to support the heat transfer element 172 relative to the host circuit board 110. For example, the support elements 182 may include one or more support posts 184 extending between the heat transfer element 172 in the upper surface 112 of the host circuit board 110. The heights of the support posts 184 define the height of the component space 180. The support posts 184 allow airflow through the component space 180. The support elements 182 support the heat transfer element 172 above the component space 180 to position the thermal bridge 200 relative to the host circuit board 110 and/or the board connector 130 to interface with the second electrical component 500.

The thermal bridge 200 is configured to be thermally coupled to the heat transfer element 172 (for example, directly coupled to the thermal surface 176 or thermally coupled to the thermal surface 176 through a layer of thermal grease or other thermal interface material) at an upper thermal interface 190 at the top of the thermal bridge 200. The thermal bridge 200 is configured to be thermally coupled to the second electrical component 500 at a lower thermal interface 192 at a bottom of the thermal bridge 200. The thermal bridge 200 dissipates heat from the second electrical component 500 (for example, from the pluggable module 600) when thermally coupled thereto. The heat transfer element 172 dissipates heat from the thermal bridge 200. The thermal bridge 200 thermally connects the second electrical component 500 and the heat transfer element 172 to transport heat away from the second electrical component 500.

In an exemplary embodiment, the thermal bridge 200 is compressible between the second electrical component 500 and the heat transfer element 172. In an exemplary embodiment, the lower thermal interface 192 is conformable to a shape of the second electrical component 500 and the upper thermal interface 190 is conformable to a shape of the heat transfer element 172 for efficient thermal transfer therebetween. For example, the thermal bridge 200 may be a stacked plate-like structure wherein the individual plates are movable relative to each other to conform to the second electrical component 500 and the heat transfer element 172. Thermal grease or other thermal interface materials may be provided at the interface(s) such as at the upper thermal interface 190 to enhance thermal transfer between the thermal bridge 200 and the other component(s).

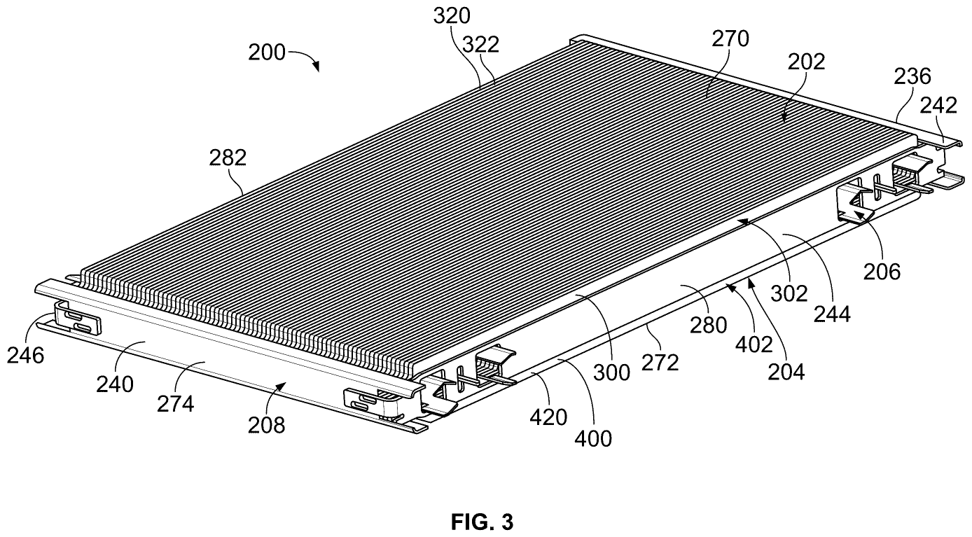

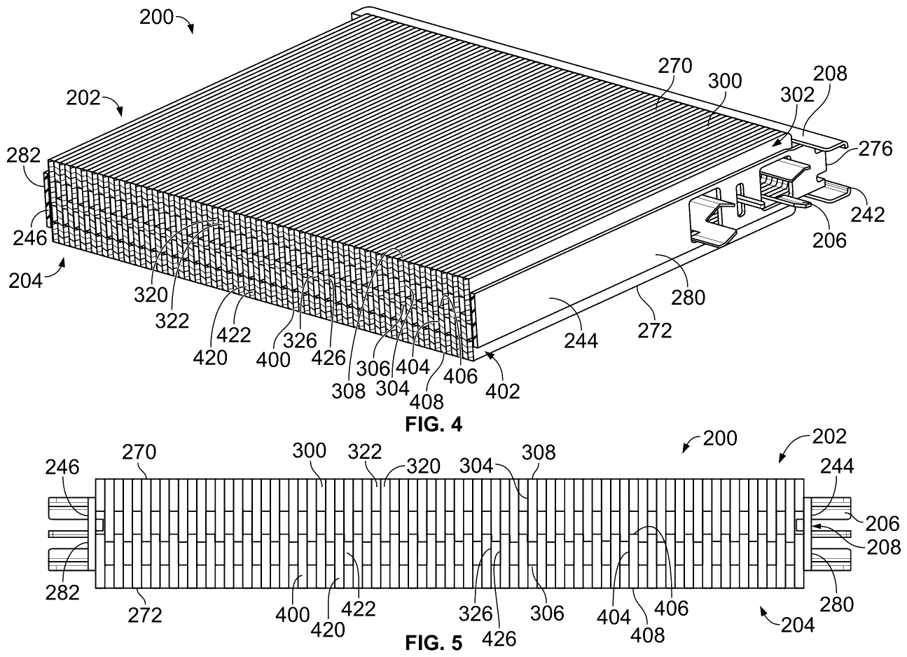

FIG. 3 is a perspective view of the thermal bridge 200 in accordance with an exemplary embodiment. FIG. 4 is a sectional view of the thermal bridge 200 in accordance with an exemplary embodiment. FIG. 5 is a cross-sectional view of the thermal bridge 200 in accordance with an exemplary embodiment. Other types of heat exchangers may be used in alternative embodiments as an intermediary thermal component between the second electrical component 500 (for example, from the pluggable module 600) and the heat transfer element 172.

In an exemplary embodiment, the thermal bridge 200 includes an upper bridge assembly 202, a lower bridge assembly 204, a spring element 206 between the upper and lower bridge assemblies 202, 204, and a bridge frame 208 for holding the upper and lower bridge assemblies 202, 204 together. The lower bridge assembly 204 is configured to thermally engage the second electrical component 500. The upper bridge assembly 202 is configured to transfer heat to the heat transfer element 172. The upper bridge assembly 202 is in thermal communication with the lower bridge assembly 204 and transfers heat away from the lower bridge assembly 204 to cool the second electrical component 500.

The spring element(s) 206 biases the upper and lower bridge assemblies 202, 204 apart. The upper and lower bridge assemblies 202, 204 are compressible relative to each other. For example, the upper and lower bridge assemblies 202, 204 are compressible between the second electrical component 500 and the heat transfer element 172 (for example, compress the spring element 206).

The bridge frame 208 provides support for the upper and lower bridge assemblies 202, 204. For example, the bridge frame 208 may surround the outer perimeter or periphery of the thermal bridge 200 to hold the components in an interior space of the bridge frame 208. The bridge frame 208 may be mounted to the heat transfer element 172, such as being fastened, clipped, latched, welded, or otherwise fixed to the heat transfer element 172. In an exemplary embodiment, the bridge frame 208 may extend along the sides and ends, leaving the top and bottom to form thermal interfaces with the second electrical component 500 and the heat transfer element 172. Optionally, the bridge frame 208 may provide internal support through the bridge assemblies 202, 204. For example, connecting spars, pins, or other types of internal connecting elements may pass through the bridge assemblies 202, 204.

In an exemplary embodiment, the spring element 206 presses the upper bridge assembly 202 outward in a first biasing direction (for example, upward) against the bridge frame 208 and the spring element 206 presses the lower bridge assembly 204 outward in a second biasing direction (for example, downward) against the bridge frame 208. The upper bridge assembly 202 and the lower bridge assembly 204 may be held by the bridge frame 208 in a manner to allow a limited amount of floating movement of the upper bridge assembly 202 and the lower bridge assembly 204 relative to the bridge frame 208.

In an exemplary embodiment, the thermal bridge 200 is parallelepiped (for example, generally box shaped). For example, the thermal bridge 200 includes a top 270, a bottom 272, a front 274, a rear 276, a first side 280, and a second side 282. The top 270 may be generally planar. The bottom 272 may be generally planar. The front 274 may be generally planar. The rear 276 may be generally planar. The first side 280 may be generally planar. The second side 282 may be generally planar. However, the thermal bridge 200 may have other shapes in alternative embodiments. The frame structure used to hold the thermal bridge 200 together is defined by the bridge frame 208. The top 270 and the bottom 272 have large surface areas to allows for a large amount of usable external surface area for heat transfer.

In an exemplary embodiment, the bridge assemblies 202, 204 each include a plurality of plates that are arranged together in plate stacks. The plates are interleaved with each other for thermal communication between the upper bridge assembly 202 and the lower bridge assembly 204. The individual plates are movable relative to each other such that the plates may be individually articulated to conform to the second electrical component 500 and/or the heat transfer element 172. For example, the individual plates may conform to the second electrical component 500 at the lower thermal interface 104 for improved contact and/or proximity between the thermal bridge 200 and the second electrical component 500 and/or the individual plates may conform to the heat transfer element 172 at the upper thermal interface 108 for improved contact and/or proximity between the thermal bridge 200 and the heat transfer element 172. A gap or space may be provided between the plates of the upper and lower bridge assemblies 202, 204 to allow compressive movement of the spring element 206 between the bridge assemblies 202, 204.

In an exemplary embodiment, the bridge frame 208 is manufactured from a plurality of frame elements, which may be connected together to form a supporting structure for the bridge assemblies 202, 204. For example, the frame elements may surround the outer perimeter of the plate stacks. The frame elements may pass through the interior of the plate stacks to hold the bridge assemblies 202, 204. In an exemplary embodiment, the bridge frame 208 includes a front rail 240, a rear rail 242, a first side rail 244 extending between the front and rear rails 240, 242, and a second side rail 246 extending between the front and rear rails 240, 242. The rails may be stamped and formed elements. In an exemplary embodiment, front and rear rails 240, 242 engage the bridge assemblies 202, 204 to limit spreading apart of the bridge assemblies 202, 204 against the opening forces of the spring element 206.

In an exemplary embodiment, the upper bridge assembly 202 includes a plurality of upper plates 300 arranged in an upper plate stack 302. In an exemplary embodiment, the lower bridge assembly 204 includes a plurality of lower plates 400 arranged in a lower plate stack 402. The upper plates 300 are interleaved with the lower plates 400 in the plate stacks 302, 402.

In an exemplary embodiment, the upper plates 300 include upper transfer plates 320 and upper spacer plates 322 between the upper transfer plates 320. Each upper plate 300 has sides 304 extending between a lower end 306 and an upper end 308 of the upper plate 300. The lower end 306 faces the lower bridge assembly 204. The upper end 308 faces outward, such as toward the heat transfer element 172. For example, there is no other component between the upper end 308 and the heat transfer element 172. However, there may be a thermal interface material or thermal grease at the upper end 308 to enhance heat transfer to the heat transfer element 172. Optionally, various upper plates 300 may have different shapes and/or heights between the upper end 306 and the lower end 308. In alternative embodiments, all of the upper plates 300 may have the same shape, such as the same height/thickness/length.

The upper ends 308 of the upper transfer plates 320 and the upper ends 308 of the upper spacer plates 322 form the upper thermal interface 190. The upper ends 308 of the upper transfer plates 320 and the upper ends 308 of the upper spacer plates 322 are configured to face and engage the heat transfer element 172, such as the thermal surface 176. The upper plates 300 are discrete from each other to allow movement relative to each other within the upper plate stack. As such, the upper ends 308 of the upper transfer plates 320 and the upper ends 308 of the upper spacer plates 322 are configured to conform to the heat transfer element 172 for efficient thermal transfer from the thermal bridge 200 to the heat transfer element 172.

In an exemplary embodiment, the lower plates 400 include lower transfer plates 420 and lower spacer plates 430 between the lower transfer plates 420. Each lower plate 400 has sides 404 extending between an upper end 406 and a lower end 408 of the lower plate 400. The upper end 406 faces the upper bridge assembly 202. For example, the upper ends 406 may face the lower ends 308 of the corresponding upper plates 300 of the upper bridge assembly 202. The lower ends 408 of the lower plates 400 face outward, such as toward the second electrical component 500. Optionally, various lower plates 400 may have different shapes and/or heights between the upper end 406 and the lower end 408. In alternative embodiments, all of the lower plates 400 may have the same shape, such as the same height/thickness/length.

In an exemplary embodiment, the lower plates 400 include lower transfer plates 420 and lower spacer plates 422. The lower spacer plates 422 are located between the lower transfer plates 420. The lower transfer plates 420 are configured to overlap with the upper transfer plates 320 to thermally couple the lower bridge assembly 204 and the upper bridge assembly 202.

In an exemplary embodiment, the upper transfer plates 320 include upper overlapping regions 326 and the lower transfer plates 420 include lower overlapping regions 426. The upper bridge assembly 202 and the lower bridge assembly 204 are internested such that the upper overlapping regions 326 thermally interface with the lower overlapping regions 426 to thermally couple the upper transfer plates 320 and the lower transfer plates 420. The amount of overlap of the overlapping regions 326, 426 increases as the thermal bridge 200 is compressed. As such, the efficiency of thermal transfer between the upper bridge assembly 202 and the lower bridge assembly 204 increases as the thermal bridge 200 is compressed.

The lower ends 408 of the lower transfer plates 420 and the lower ends 408 of the lower spacer plates 422 form the lower thermal interface 192. The lower ends 408 of the lower transfer plates 420 and the lower ends 408 of the lower spacer plates 422 are configured to face and engage the second electrical component 500. The lower plates 400 are discrete from each other to allow movement relative to each other within the lower plate stack. As such, the lower ends 408 of the lower transfer plates 420 and the lower ends 408 of the lower spacer plates 422 are configured to conform to the second electrical component 500 for efficient thermal transfer from the second electrical component 500 to the thermal bridge 200.

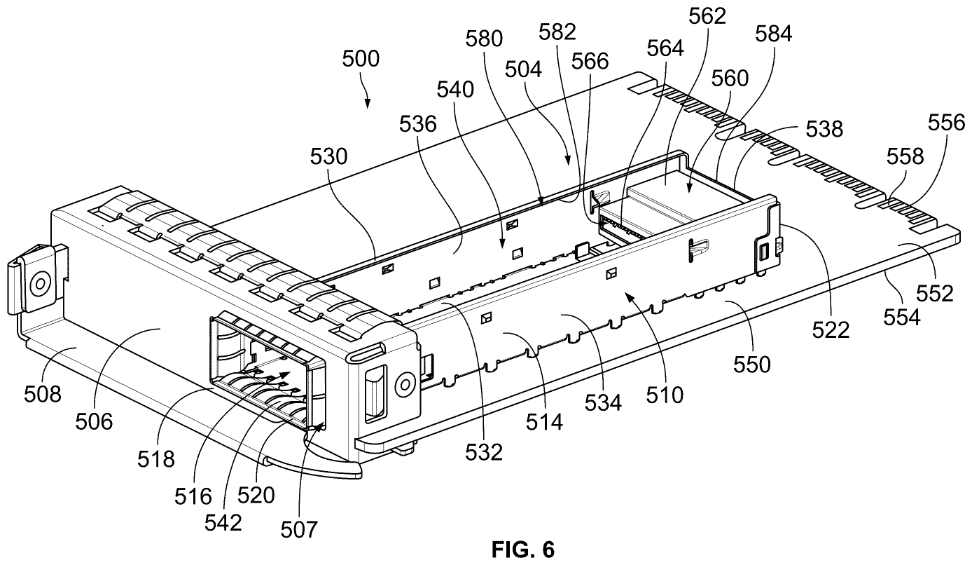

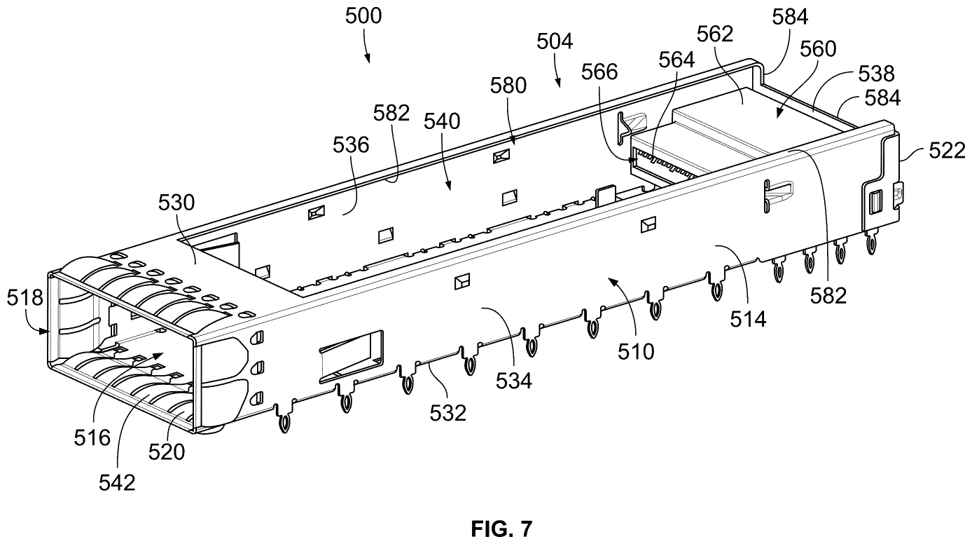

FIG. 6 is a perspective view of the second electrical component 500 in accordance with an exemplary embodiment. FIG. 7 is a perspective view of a portion of the second electrical component 500 in accordance with an exemplary embodiment. The second electrical component 500 is configured to be received in the component space 180 (FIG. 1) to be thermally and electrically coupled to the first electrical component 100.

In an exemplary embodiment, the second electrical component 500 includes a circuit card 550 (FIG. 6) and a receptacle connector assembly 504 mounted to the circuit card 550. The pluggable module 600 (shown in FIG. 1) is configured to be electrically connected to the receptacle connector assembly 504. The pluggable module 600 is electrically connected to the circuit card 550 through the receptacle connector assembly 504. In an exemplary embodiment, the second electrical component 500 is a network interface card having a pluggable interface for plugging into the first electrical component 100.

In an exemplary embodiment, the second electrical component 500 includes a faceplate 506 at a front of the second electrical component 500. The faceplate 506 is configured to interface with the first electrical component 100, such as to provide shielding and/or an environmental cover for the communication system 10.

In an exemplary embodiment, the second electrical component 500 includes a bracket 508 at the front of the second electrical component 500. The bracket 508 may provide a surface for holding the second electrical component 500 for mating and unmating. The bracket 508 may be used to mechanically secure the second electrical component 500 to the first electrical component 100, such as including a latch or other securing feature to secure the second electrical component 500 to the first electrical component 100.

In an exemplary embodiment, the receptacle connector assembly 504 includes a receptacle cage 510 and a receptacle connector 560 adjacent the receptacle cage 510. The receptacle connector 560 is received in the receptacle cage 510, such as at the rear of the receptacle cage 510. In various embodiments, the receptacle cage 510 is enclosed and provides electrical shielding for the receptacle connector 560. The pluggable module 600 is configured to be loaded into the receptacle cage 510 and at least partially surrounded by the receptacle cage 510. In an exemplary embodiment, the receptacle cage 510 is a shielding, stamped and formed cage member that includes a plurality of shielding walls 514 that define one or more module channels 516 for receipt of the corresponding pluggable module(s) 600.

In the illustrated embodiment, the receptacle cage 510 is a single port receptacle cage configured to receive a single pluggable module 600. In other various embodiments, the receptacle cage 510 may be a ganged cage member having a plurality of ports ganged together in a single row and/or a stacked cage member having multiple ports stacked as an upper port and a lower port. The receptacle cage 510 includes a module channel 516 having a module port 518 open to the module channel 516. The module channel 516 receives the pluggable module 600 through the module port 518. In an exemplary embodiment, the receptacle cage 510 extends between a front end 520 and a rear end 522. The module port 518 is provided at the front end 520. The module port 518 includes a polarization feature (for example, slot or keyway) for keyed mating with the pluggable module 600. Any number of module channels 516 may be provided in various embodiments arranged in a single column or in multiple columns (for example, 2×2, 3×2, 4×2, 4×3, 4×1, 2×1, and the like). Optionally, multiple receptacle connectors 560 may be arranged within the receptacle cage 510, such as when multiple rows and/or columns of module channels 516 are provided.

In an exemplary embodiment, the shielding walls 514 of the receptacle cage 510 include a first end wall 530, a second end wall 532, a first side wall 534, a second side wall 536, a rear wall 538 and may include a front wall. The side walls 534, 536 extend between the end walls 530, 532. In various embodiments, the first end wall 530 is at a top of the receptacle cage 510, and thus defines an upper wall 530, and the second end wall 532 is at a bottom of the receptacle cage 510, and thus defines a lower wall 532. Other orientations are possible in alternative embodiments, such as the second end wall 532 or one of the side walls 534, 536 defining the top wall. The second end wall 532 may face, and possibly rest on, the circuit card 550. In various embodiments, the receptacle cage 510 may be provided without the lower wall 532.

The walls 514 define a cavity 540. For example, the cavity 540 may be defined by the first end wall 530, the second end wall 532, the side walls 534, 536 and the rear wall 538. The cavity 540 includes the module channel 516. In various embodiments, the cavity 540 receives the receptacle connector 560, such as at the rear end 522. Other walls 514 may separate or divide the cavity 540 into additional module channels 516, such as in embodiments using ganged and/or stacked receptacle cages. For example, the walls 514 may include one or more vertical divider walls between ganged module channels 516. In various embodiments, the walls 514 may include a separator panel between stacked upper and lower module channels 516.

In an exemplary embodiment, the receptacle cage 510 may include one or more springs 542 at the front end 520 for providing electrical shielding for the module channels 516. For example, the springs 542 may be provided at the port 518 to electrically connect with the pluggable module 600 received in the module channel 516. The springs 542 may be electrically connected to the faceplate 506, such as being received in an opening or socket 507 formed in the faceplate 506. The springs 542 include spring fingers or other deflectable features that are configured to interface with the pluggable module 600 and/or the faceplate 506.

The pluggable module 600 is configured to be loaded through the port 518 at the front end 520 to mate with the receptacle connector 560. The shielding walls 514 of the receptacle cage 510 provide electrical shielding around the receptacle connector 560 and the pluggable module 600, such as around the mating interface between the receptacle connector 560 and the pluggable module 600. The pluggable module 600 is electrically connected to the circuit card 550 via the receptacle connector 560.

In an exemplary embodiment, the circuit card 550 includes an upper surface 552 and a lower surface 554. The host circuit board 550 includes one or more circuits (for example, traces, pads, vias, and the like) on one or more layers of the circuit card 550. The circuit card 550 includes a mating interface at a card edge 556 of the circuit card 550. The mating interface at the card edge 556 is configured to be mated with the board connector 130 (FIG. 1) of the first electrical component 100. The circuit card 550 includes contact pads 558 at the card edge 556 configured to be electrically connected to board contacts of the board connector 130. The contact pads 558 may be provided at the upper surface 552 and/or the lower surface 554. The circuit card 550 may host other electrical components, such as a processor, IC component, memory component, or other types of electrical components.

The receptacle connector 560 is electrically connected to the circuit card 550. For example, the receptacle connector 560 may be mounted to the upper surface 552 of the circuit card 550. The receptacle connector 560 may be soldered to circuits of the circuit card 550. In an exemplary embodiment, the receptacle connector 560 includes a receptacle connector housing 562 holding receptacle connector contacts 564. The receptacle connector contacts 564 are configured to be electrically connected to the corresponding circuits (for example, pads, of the circuit card 550). In an exemplary embodiment, the receptacle connector housing 562 is a card edge connector having a card slot 566 at a front of the receptacle connector housing 562. The card slot 566 is configured to receive the card edge of the module circuit card 616 of the pluggable module 600 in a loading direction, which may be parallel to the upper surface 552 of the circuit card 550. Other types of electrical connectors may be used in alternative embodiments.

In an exemplary embodiment, the receptacle cage 510 includes a thermal opening 580 configured to receive the thermal bridge 200. The thermal opening 580 is open to the module channel 516 to allow the thermal bridge 200 to interface with the pluggable module 600. The thermal opening 580 is sized and shaped to receive the thermal bridge 200. In an exemplary embodiment, the thermal opening 580 is open at the upper wall 530 and open at the rear wall 538 to receive the thermal bridge 200 of the heat transfer assembly 170. The thermal opening 580 is open to allow the thermal bridge 200 to interface with the pluggable module 600 in the module channel 516.

In an exemplary embodiment, the thermal opening 580 is continuous along the upper wall 530 and the rear wall 538 to allow positioning of the thermal bridge 200 in the module channel 516 through the upper wall 530 and through the rear wall 538. The thermal opening 580 is continuous along the upper wall 530 and the rear wall 538. For example, the upper wall 530 includes upper edges 582 defining a portion of the thermal opening 580 and the rear wall 538 includes rear edges 584 defining a portion of the thermal opening 580. The upper edges 582 and the rear edges 584 are continuous with each other. For example, the upper edges 582 are continuous with the rear edges 584 to form the continuous thermal opening 580. In an exemplary embodiment, the thermal opening 580 is open forward of the receptacle connector 560, open above the receptacle connector 560, and open rearward of the receptacle connector 560. The thermal opening 580 allows positioning of the thermal bridge 200 in the module channel 516 through the upper wall 530 and through the rear wall 538.

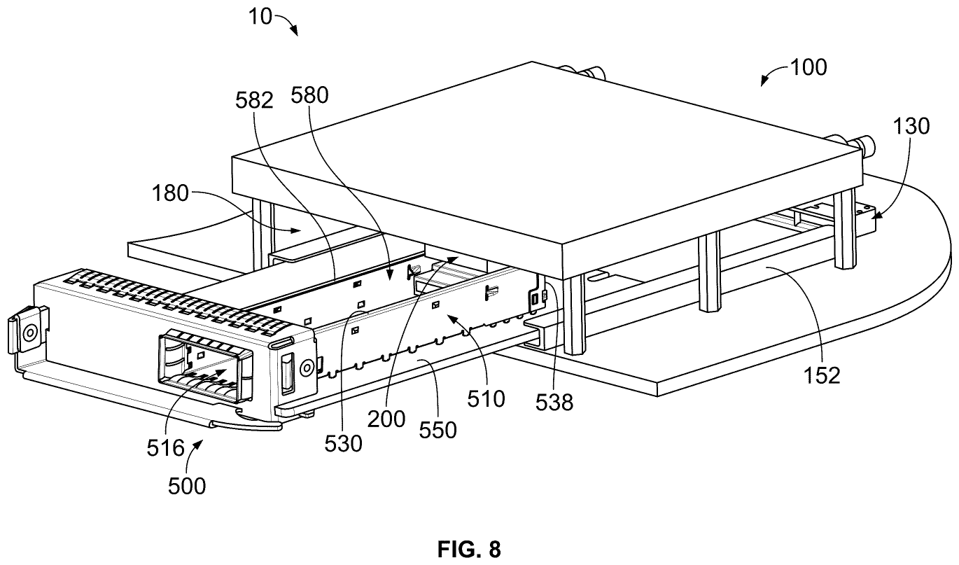

FIG. 8 is a perspective view of the communication system 10 showing the second electrical component 500 partially mated with the first electrical component 100. During mating, the circuit card 550 is loaded into the guide rails 152. The guide rails 152 guide loading of the second electrical component 500 into the component space 180. The guide rails 152 guide the circuit card 550 to the board connector 130.

During mating, the thermal bridge 200 is received in the thermal opening 580. The guide rails 152 align the circuit card 550, and thus the receptacle cage 510, with the thermal bridge 200. For example, the thermal opening 580 is aligned with the thermal bridge 200. The thermal opening 580 is open at the rear and the top of the receptacle cage 510 to receive the thermal bridge 200. For example, during mating, the thermal opening 580 initially receives the thermal bridge 200 through the rear wall 538, such as through the rear edges 584 of the thermal opening 580. Further loading of the second electrical component 500 into the component space 180 loads the thermal bridge 200 through the upper wall 530, such as through the upper edges 582. Due to the loading in the horizontal loading direction, without the thermal opening 580 in the rear wall 538, the thermal bridge 200 would be unable to load into the thermal opening 580 in the upper wall 530. When fully loaded, the thermal bridge 200 is located in the module channel 516 to interface with the pluggable module 600 (FIG. 1) when the pluggable module 600 is loaded into the module channel 516.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A communication system comprising:
a first electrical component comprising a host circuit board having a first surface and a board connector mounted to the first surface, the first electrical component comprising a heat transfer assembly including a heat transfer element, the heat transfer element including a thermal surface spaced apart from the first surface forming a component space between the first surface and the thermal surface, the heat transfer assembly including a thermal bridge in the component space including a first thermal interface thermally coupled to the thermal surface and a second thermal interface opposite the first thermal surface; and
a second electrical component received in the component space and being thermally and electrically coupled to the first electrical component, the second electrical component comprising a circuit card having a first surface and a receptacle connector mounted to the first surface, the receptacle connector configured to be electrically connected to a pluggable module, the circuit card being electrically connected to the board connector, the second electrical component comprising a receptacle cage coupled to the circuit card, the receptacle cage including cage walls including an upper wall, a lower wall, a first side wall, a second side wall, and a rear wall, the receptacle cage including a module channel between the upper and lower walls and between the first and second sides walls and between the front and rear walls, the module channel receiving the receptacle connector therein at a rear of the receptacle cage, the module channel configured to receive the pluggable module through a port at a front of the receptacle cage, the receptacle cage including a thermal opening open at the upper wall and the rear wall, the thermal opening receiving the thermal bridge of the heat transfer assembly to allow the thermal bridge to interface with the pluggable module in the module channel.

2. The communication system of claim 1, wherein the thermal bridge is mounted to the heat transfer element such that the thermal bridge is mechanically and thermally coupled to the transfer element.

3. The communication system of claim 1, wherein the thermal bridge includes a bridge frame, the bridge frame being fixed to the heat transfer element.

4. The communication system of claim 1, wherein the thermal bridge comprises:
an upper bridge assembly including a plurality of upper transfer plates, each upper transfer plate having sides between an upper end and a lower end, the upper ends of the upper transfer plates being thermally coupled to the thermal surface of the heat transfer element;
a lower bridge assembly including a plurality of lower transfer plates, each lower transfer plate having sides between an upper end and a lower end, the sides of the lower transfer plates configured to interface the sides of the upper transfer plates to thermally transfer heat from the lower bridge assembly to the upper bridge assembly, the lower ends of the lower transfer plates configured to face and thermally couple to the second electrical component; and
a spring element positioned between the upper bridge assembly and the lower bridge assembly, the spring element including an upper spring member engaging the upper transfer plates to bias the upper transfer plates with an opening force generally away from the lower transfer plates, the spring element including a lower spring member engaging the lower transfer plates to bias the lower transfer plates with an opening force generally away from the upper transfer plates.

5. The communication system of claim 4, wherein the spring element is compressible allowing the upper transfer plates to move relative to the lower transfer plates to conform the upper transfer plates to the heat transfer element and to conform the lower transfer plates to the second electrical component.

6. The communication system of claim 4, wherein the upper transfer plates include upper overlapping regions and the lower transfer plates include lower overlapping regions, the upper bridge assembly and the lower bridge assembly being internested such that the upper overlapping regions thermally interface with the lower overlapping regions to thermally couple the upper transfer plates and the lower transfer plates.

7. The communication system of claim 1, wherein the heat transfer assembly includes a support element coupled to the host circuit board, the support element supporting the heat transfer element above the component space to position the thermal bridge relative to the board connector to interface with the second electrical component.

8. The communication system of claim 1, further comprising a guide rail positioned relative to the board connector to guide mating of the second electrical component with the board connector.

9. The communication system of claim 8, wherein the guide rail includes a guide track configured to receive a circuit card of the second electrical component.

10. The communication system of claim 1, wherein the board connector includes a board connector housing holding board connector contacts, the board connector housing including a card slot configured to receive a circuit card of the second electrical component.

11. The communication system of claim 1, wherein the thermal opening is continuous along the upper wall and the rear wall.

12. The communication system of claim 1, wherein the thermal opening is open forward of the receptacle connector, above the receptacle connector, and rearward of the receptacle connector.

13. The communication system of claim 1, wherein the thermal opening allows positioning of the thermal bridge in the module channel through the upper wall and through the rear wall.

14. The communication system of claim 1, wherein the upper wall includes upper edges defining a portion of the thermal opening and the rear wall includes rear edges defining a portion of the thermal opening, the upper edges and the rear edges being continuous with each other.

15. The communication system of claim 1, wherein the circuit card is a network interface card including a card edge configured to be plugged into a card slot of the second electrical component.

16. The communication system of claim 1, wherein the receptacle connector includes a receptacle connector housing holding receptacle connector contacts, the receptacle connector housing having a card slot configured to receive a module circuit card of the pluggable module.

17. The communication system of claim 1, further comprising a faceplate at a front of the circuit card, the faceplate including a socket receiving a front of the receptacle cage and configured to receive the pluggable module, the faceplate configured to interface with the second electrical component.

18. An electrical component comprising:
a circuit card including a first surface;
a receptacle connector mounted to the first surface of the circuit card, the receptacle connector configured to be electrically connected to a pluggable module; and
a receptacle cage coupled to the circuit card, the receptacle cage including cage walls including an upper wall, a lower wall, a first side wall, a second side wall, and a rear wall, the receptacle cage including a module channel between the upper and lower walls and between the first and second sides walls and between the front and rear walls, the module channel receiving the receptacle connector therein at a rear of the receptacle cage, the module channel configured to receive the pluggable module through a port at a front of the receptacle cage, the receptacle cage including a thermal opening open at the upper wall and the rear wall configured to receive a thermal bridge of a heat transfer assembly to allow the thermal bridge to interface with the pluggable module in the module channel.

19. The electrical component of claim 18, wherein the thermal opening is continuous along the upper wall and the rear wall to allow positioning of the thermal bridge in the module channel through the upper wall and through the rear wall.

20. The electrical component of claim 18, wherein the thermal opening is continuous along the upper wall and the rear wall.

21. The electrical component of claim 18, wherein the thermal opening is open forward of the receptacle connector, above the receptacle connector, and rearward of the receptacle connector.

22. The electrical component of claim 18, wherein the thermal opening allows positioning of the thermal bridge in the module channel through the upper wall and through the rear wall.

23. The electrical component of claim 18, wherein the upper wall includes upper edges defining a portion of the thermal opening and the rear wall includes rear edges defining a portion of the thermal opening, the upper edges and the rear edges being continuous with each other.

24. The electrical component of claim 18, wherein the circuit card is a network interface card including a card edge configured to be plugged into a card slot of the mating electrical component.

25. The electrical component of claim 18, wherein the receptacle connector includes a receptacle connector housing holding receptacle connector contacts, the receptacle connector housing having a card slot configured to receive a module circuit card of the pluggable module.

26. The electrical component of claim 18, further comprising a faceplate at a front of the circuit card, the faceplate including a socket receiving a front of the receptacle cage and configured to receive the pluggable module, the faceplate configured to interface with the mating electrical component.
